(19) United States
(12) Patent Application Publication
(10) Pub. No.: US 2014/0132326 A1
(43) Pub. Date: May 15, 2014

(54) PULSE NOISE SUPPRESSION CIRCUIT AND PULSE NOISE SUPPRESSION METHOD THEREOF

(71) Applicant: Electronics and Telecommunications Research Institute, Daejeon (KR)

(72) Inventors: Yi-Gyeong KIM, Daejeon (KR); Tae Moon ROH, Daejeon (KR); Jong-Kee KWON, Daejeon (KR)

(21) Appl. No.: 13/922,647

(22) Filed: Jun. 20, 2013

(30) Foreign Application Priority Data
Nov. 15, 2012 (KR) 10-2012-0129580

(51) Int. Cl. H03K 5/08

(52) U.S. Cl. CPC H03K 5/088
USPC 327/311

(57) ABSTRACT

Provided is a pulse noise suppression circuit. The pulse noise suppression circuit includes a filter circuit converting an input signal of a pulse type into an increasing or decreasing filter signal, a level reset circuit resetting the filter signal in response to the input signal and an output signal and an output circuit converting the filter signal into the output signal of a pulse type, wherein the level reset circuit resets the filter signal to have a high level when the input signal and the output signal all have a high level, and resets the filter signal to have a low level when the input signal and the output signal all have a low level.

### CROSS-REFERENCE TO RELATED APPLICATIONS

This U.S. non-provisional patent application claims priority under 35 U.S.C. §119 of Korean Patent Application No. 10-2012-0129580, filed on Nov, 15, 2012, the entire contents of which are hereby incorporated by reference.

### BACKGROUND OF THE INVENTION

The present invention disclosed herein relates to a pulse noise suppression circuit and a pulse noise suppression method thereof in order to reject a pulse noise in digital signal transfer between chips.

In digital signal transfer between chips, a pulse noise may be flowed into the signal transfer due to an external interference signal. A typical technology for reducing an effect of inflow of the pulse noise is as shown in FIG. 1. The effect of the pulse noise may be reduced by using characteristics of a low frequency filter through an inverter INV1 and a capacitor C.

However, there are two limitations in the typical technology for reducing the pulse noise. A first of them is that an error signal may be generated for continuous pulse noises of a short interval. As may be seen in FIG. 2, when there is continuous inflow of a pulse noise in a short interval, a capacitor voltage Vfilter overlaps each other during charging/discharging. Then a wrong output pulse may be generated as the capacitor voltage Vfilter becomes high. A second of the limitations is that an input pulse width and an output pulse width may be varied when the pulse noise is flowed into a middle of a normal signal. As shown in FIG. 3, a low level pulse noise may be flowed into a high level input signal Vin. Due to this, a capacitor voltage Vfilter becomes lowered during the pulse noise, and then becomes high again. However, the capacitor voltage Vfilter may not reach a perfect high level. Accordingly an output pulse width tₒᵤₜ becomes shorter than an input pulse width tᵢₙ. In this case, a critical information loss may occur in a system which transfers information through a pulse width.

### SUMMARY OF THE INVENTION

The present invention provides a pulse noise suppression circuit having a simple configuration and low power consumption, and a pulse noise suppression method thereof.

Embodiments of the present invention provide pulse noise suppression circuits including a filter circuit converting an input signal of a pulse type into an increasing or decreasing filter signal; a level reset circuit resetting the filter signal in response to the input signal and an output signal; and an output circuit converting the filter signal into the output signal of a pulse type, wherein the level reset circuit resets the filter signal to have a high level when the input signal and the output signal all have a high level, and resets the filter signal to have a low level when the input signal and the output signal all have a low level.

In other embodiments of the present invention, pulse noise suppression methods includes: converting an input signal of a pulse type into a filter signal of an increasing or decreasing type; performing a reset operation of the filter signal in response to the input signal and an output signal; and converting the filter signal into the output signal of a pulse type, wherein, in the performing of a reset operation, when the input and output signals all have a high level, the filter signal is reset to have a high level, and when the input and output signals all have a low level, the filter signal is reset to have a low level.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a circuit diagram of a typical technology for suppressing a pulse noise;

FIG. 2 is a timing diagram when a continuous pulse noise is flowed into the circuit in FIG. 1;

FIG. 3 is a timing diagram when a pulse noise is flowed into a middle of a normal signal provided to the circuit in FIG. 1;

FIG. 4 is a block diagram illustrating a pulse suppression circuit according to an embodiment of the present invention;

FIG. 5 is a detailed circuit diagram of the pulse suppression circuit according to an embodiment of the present invention;

FIG. 6 is a timing diagram when a normal signal is provided to the circuit in FIG. 5;

FIG. 7 is a timing diagram illustrating a pulse noise suppression method when a continuous pulse noise having a high level High at a short interval is flowed into the circuit in FIG. 5;

FIG. 8 is a timing diagram illustrating a pulse noise suppression method when a continuous pulse noise having a low level Low at a short interval is flowed into the circuit in FIG. 5;

FIG. 9 is a timing diagram illustrating a pulse noise suppression method when a low level pulse noise is flowed into a high level input signal in the circuit in FIG. 5;

FIG. 10 is a timing diagram illustrating a pulse noise suppression method when a high level pulse noise is flowed into a low level input signal in the circuit in FIG. 5;

FIG. 11 is a detailed circuit diagram of a pulse suppression circuit according to another embodiment of the present invention; and

FIG. 12 is a timing diagram illustrating an effect of the circuit in FIG. 11.

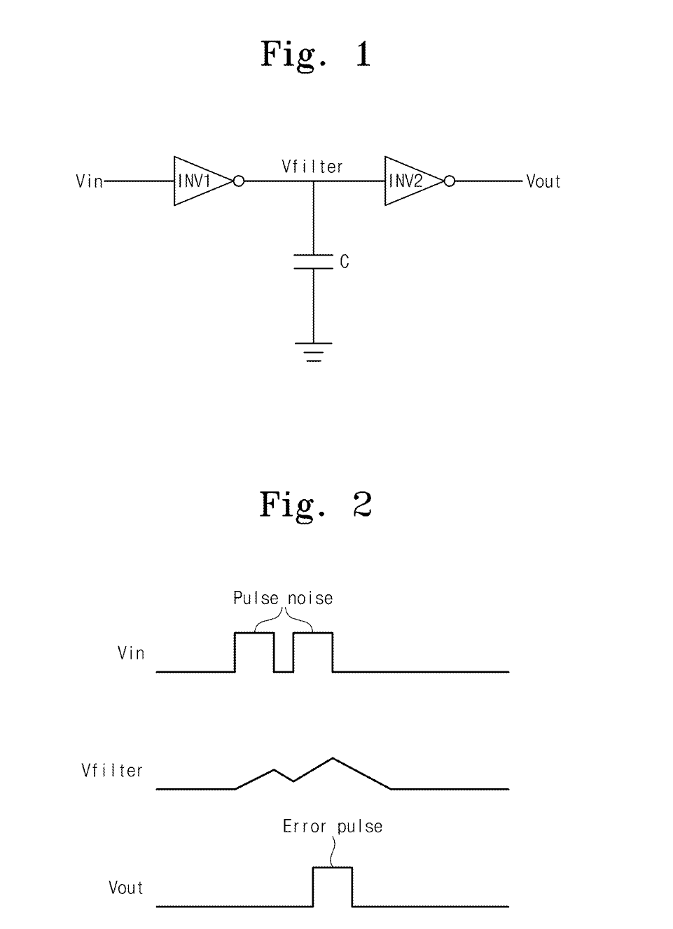

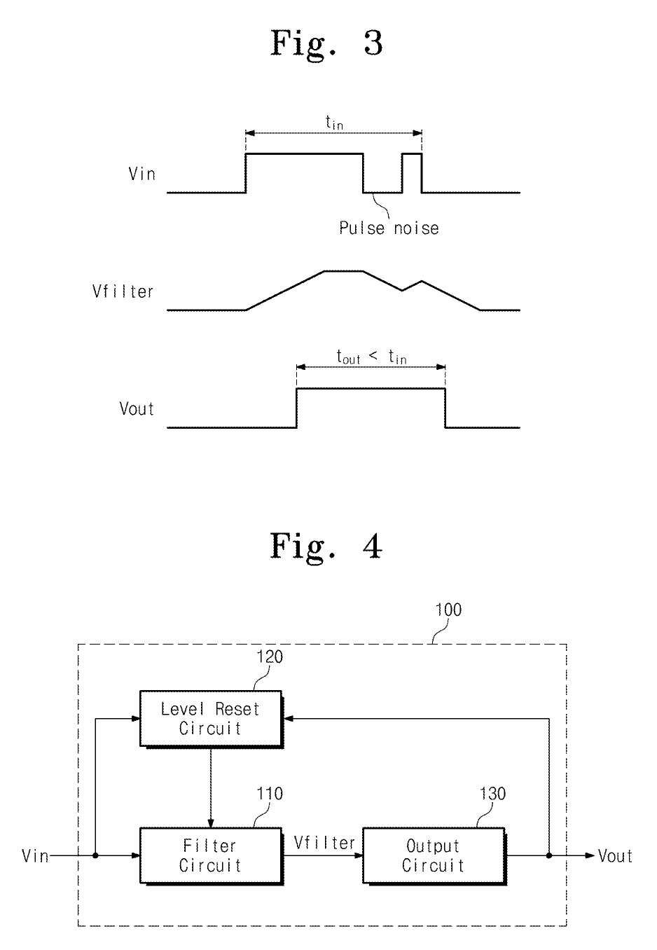

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Hereinafter, it will be described about an exemplary embodiment of the present invention in conjunction with the accompanying drawings. Like reference numerals refer to like elements throughout.

A pulse width discriminating a normal signal from a pulse noise is defined as a pulse noise reference time ΔT. The pulse noise reference time ΔT is determined by characteristics of elements included in a circuit.

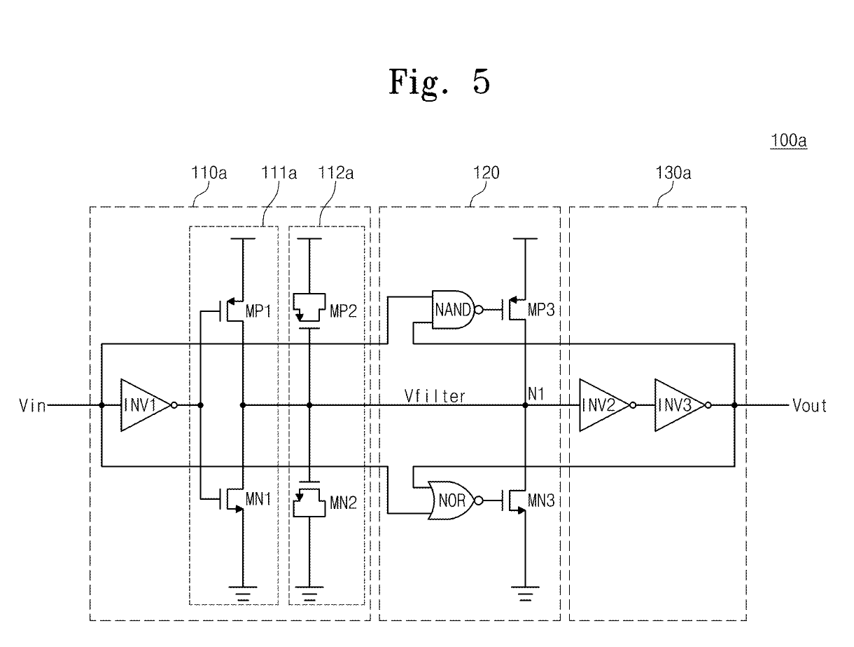

FIG. 4 is a block diagram illustrating a pulse noise suppression circuit according to an embodiment of the present invention. Referring to FIG. 4, the pulse noise suppression circuit includes a filter circuit 110, a level reset circuit 120, and an output circuit 130. The pulse noise suppression circuit 100 may effectively remove a pulse noise through the filter circuit 110 and the level reset circuit 120, and output a signal removed the pulse noise through the output circuit 130. The pulse noise reference time ΔT is determined by combining a rate of voltage rise of a filter signal Vfilter determined by characteristics of elements forming the filter circuit 110 and a reference voltage of the output circuit 130.

The filter circuit 110 receives an input signal Vin of a pulse type, which is a digital signal, by using characteristics of a low frequency filter, and converts the input signal Vin into a filter signal Vfilter having a gradually increasing and decreasing type. The filter signal Vfilter is transmitted to an input stage of the output circuit 130.

The level reset circuit 120 resets the filter signal Vfilter in response to the input signal Vin and an output signal Vout. For example, when the input signal Vin and the output signal Vout all have a low level Low, the level reset circuit 120 resets the filter signal Vfilter to have a low level Low. When the input signal Vin and the output signal Vout all have a high level High, the level reset circuit 120 resets the filter signal Vfilter to have a high level High. The input signal Vin and the output signal Vout have different levels, the level reset circuit 120 does not reset the filter signal Vfilter. In this case, the filter signal Vfilter passing through the filter circuit 110 is transferred to the output circuit 130 without change.

The output circuit 130 receives the filter signal Vfilter. When a voltage level of the filter signal Vfilter is higher than the reference voltage of the output circuit 130, the output circuit 130 converts the filter signal Vfilter to an output signal Vout of a high level High. When a voltage level of the filter signal Vfilter is lower than the reference voltage of the output circuit 130, the output circuit 130 converts the filter signal Vfilter into an output signal Vout of a low level Low.

FIG. 5 is a detailed circuit diagram of a pulse noise suppression circuit according to an embodiment of the present invention. The pulse noise suppression circuit 100a includes a filter circuit 110a, a level reset circuit 120a and an output circuit 130a. Functions and characteristics of the pulse noise suppression circuit 110a are the same as those of the pulse noise suppression circuit 100.

The filter circuit 110a includes an inverter INV1, a driver circuit 111a and a capacitor circuit 112a. Due to characteristics of a low frequency filter configured of a combination of the driver circuit 111a and the capacitor circuit 112a, the filter circuit 100a converts an input signal Vin of a pulse type into a gradually increasing or decreasing filter signal Vfilter. The converted filter signal Vfilter is transferred to an input stage of the output circuit 130a.

The inverter INV1 inverts the input signal Vin and transfers to the driver circuit 111a. The inverter INV1 is a typical inverter circuit.

The driver circuit 111a includes a P-channel metal-oxide-semiconductor (PMOS) transistor MP1 and an N-channel metal-oxide-semiconductor (NMOS) transistor MN1. The PMOS transistor MP1 and the NMOS transistor MN1 have a smaller current amount flowing therethrough than elements used in a typical inverter INV1. The driver circuit 111a is combined with the capacitor circuit 112a to control the filter signal Vfilter to be gradually increased or decreased. It is well understood that the driver circuit 111a is not limited thereto, and may be variously applied to an inverter or the like which adopts elements having a smaller current amount flowing therethrough than a typical inverter INV1.

The capacitor circuit 112a includes a PMOS transistor MP2 and an NMOS transistor MN2. The PMOS transistor MP2 and the NMOS transistor MN2 form a pair to play a role of a capacitor of a low frequency filter. The PMOS transistor MP2 and NMOS transistor MN2 enable the filter signal Vfilter to be gradually increased or decreased by charging and discharging. The capacitor circuit 112a is not limited thereto. It will be well understood that the capacitor circuit 112a is variously applied to a parasitic capacitor having capacitor characteristics of charging/discharging a charge in the filter circuit 110a, a MOS capacitor (MOSCAP) using transistors, or a capacitor formed by laminating a dielectric film and a conductor film in a manufacturing process of the filter circuit 110a.

The level reset circuit 120 includes a NAND gate NAND, a NOR gate NOR, a PMOS switch MP3, and an NMOS switch MN3. When a pulse noise having a pulse width shorter than the pulse noise reference time ΔT is flowed into the input signal Vin, the level reset circuit 120 rapidly resets the filter signal Vfilter to have a low level Low. Then a voltage level of the filter signal Vfilter does not become higher than the reference voltage of the output circuit 130. Their configurations and operations are described below.

The NAND gate NAND controls the PMOS switch MP3 in response to the input signal Vin and the output signal Vout. The source of the PMOS switch MP3 is connected to a power supply stage, and the drain thereof is connected to a node N1. For example, when a signal is not applied, the input signal Vin has a low level Low. Then an output value of the NAND gate NAND is a high level High. When a normal signal is applied, the input signal Vin has a high level and the filter signal Vfilter gradually increases. From a time when the signal is input and after the pulse noise reference time ΔT, the voltage level of the filter signal Vfilter is higher than the reference voltage of the output circuit 130a, the output signal Vout becomes to have a high level High. Then an output value of the NAND gate NAND changes into a low level Low and the PMOS switch is turned on. Therefore, the filter signal Vfilter is reset to have a high level High.

The NOR gate NOR controls the NMOS switch MN3 in response to the input signal Vin and the output signal Vout. The source of the NMOS switch MN3 is connected to ground and the drain thereof is connected to a node N1. For example, when a signal is not applied, the input signal Vin and the output signal Vout all have a low level Low, an output value of the NOR gate NOR is a high level High. Therefore, the NMOS switch MN3 maintains a turned-on state. In this case, the filter signal Vfilter is maintained to have a low level Low. When a pulse noise having a pulse width shorter than the reference time ΔT is input, the input signal Vin has a high level High, Then an output of the NOR gate NOR becomes to have a low level Low and the NMOS switch MN3 is turned off. Since the pulse width of the pulse noise is shorter than the reference time ΔT, the input signal Vin becomes to have again a low level Low, while the output signal Vout is still in a low level state. Then NMOS switch MN3 is turned on again, and the filter signal Vfilter having been gradually increased is rapidly reset to have a low level Low.

When the input signal Vin and the output signal Vout are different from each other, the PMOS switch MP3 and the NMOS switch MN3 all become turned off. When the input signal Vin and the output signal Vout all have a high level High, only the PMOS switch MP3 is turned on. When the input signal Vin and the output signal Vout all have a low level Low, only the NMOS switch MN3 is turned on. Therefore, there is not a case where the two switches are simultaneously turned on. The filter signal Vfilter reset by the level reset circuit 120 is transferred to the output circuit 130a.

The output circuit 130a includes two inverters INV2 and INV3. The inverter INV2 converts the filter signal Vfilter into a digital signal to transfer to the inverter INV3. A voltage level of the filter signal Vfilter is lower than a threshold voltage of the inverter INV2, the inverter INV2 converts the filter signal Vfilter to a low level Low. When the voltage level is higher than a threshold voltage of the inverter INV2, the inverter INV2 converts the filter signal Vfilter into a high level High. The inverter INV3 inverts a signal transferred from the inverter INV2 to output as the output signal Vout.

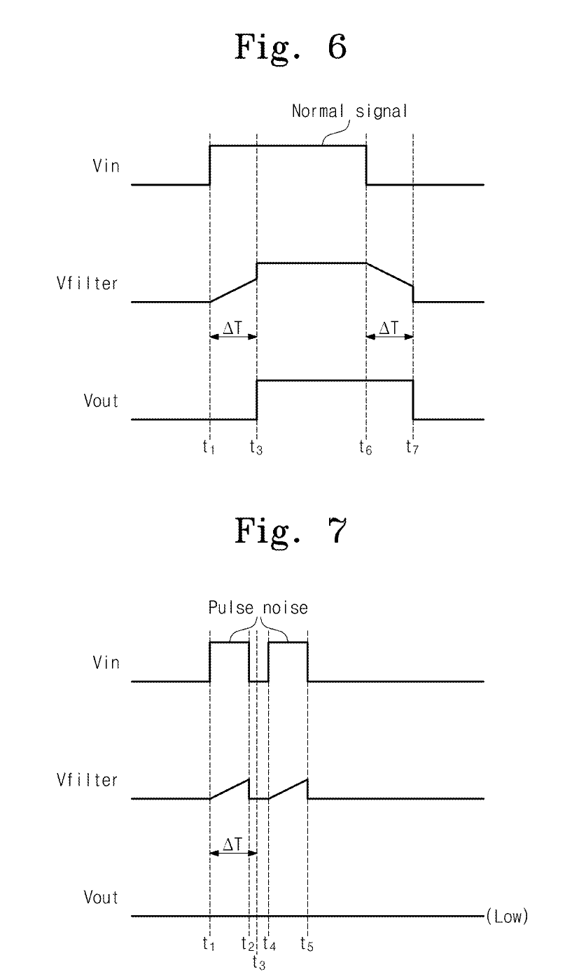

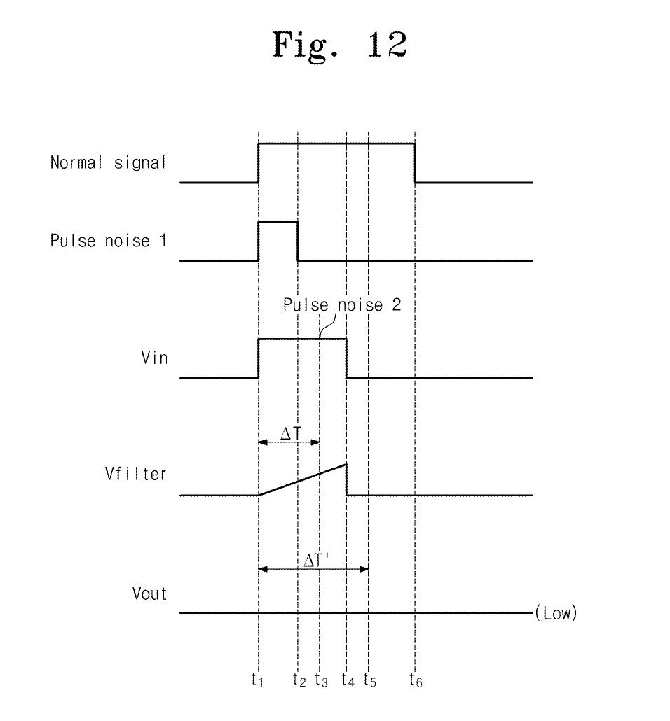

FIGS. 6 to 10 are timing diagrams illustrating exemplary pulse noise suppression methods. The pulse noise suppression method will be described with reference to FIGS. 6 to 10. Values of t1 to t7 used in FIGS. 6 to 8, FIGS. 9 and 10, or FIG. 12 may not be the same.

FIG. 6 is a timing diagram when a normal signal is applied to the circuit in FIG. 5. When the normal signal is input as the input signal Vin at a time t1, the filter signal Vfilter begins to be gradually increased by the filter circuit 110a. The output signal Vout is maintained to have a low level Low by the output circuit 130a. The PMOS switch MP3 and the NMOS switch MN3 are all in a turned-off state by output values of the NAND gate NAND and the NOR gate NOR between a time t1 and a time t3. At a time t3 after the pulse noise reference time ΔT passes from the time t1, a voltage level of the filter signal becomes higher than the reference level of the output circuit 130a. Then the output signal Vout becomes to have a high level High. Since the input signal Vin and the output signal Vout all have a high level High, an output value of the NAND gate NAND is a low level Low. Then the PMOS switch MP3 is turned on, and the filter signal Vfilter is rapidly reset to have a high level High. The NMOS switch MN3 is still in a turned-off state. At a time t6, the input signal Vin has a low level Low, an output value of the NAND gate NAND becomes to be a high level High. Then the PMOS switch MP3 is turned off and the filter signal Vfilter gradually decreases. The output signal Vout is maintained to have a high level High by the output circuit 130a. The PMOS switch MP3 and the NMOS switch MN3 are all in a turned-off state by output values of the NAND gate NAND and the NOR gate NOR between the time t6 and a time t7. At the time t7 after the pulse noise reference time ΔT passes from the time t6, a voltage level of the filter signal Vfilter becomes lower than the reference level of the output circuit 130a and the output signal Vout becomes to have a low level Low. Since the input signal

Vin and the output signal Vout all have a low level Low, an output value of the NOR gate NOR is a high level High. Then the NMOS switch MN3 is turned on, and the filter signal Vfilter is rapidly reset to have a low level Low. The PMOS switch MP3 is still in a turned-off state.

FIG. 7 is a timing diagram illustrating a pulse noise suppression method when a continuous pulse noise having a high level High at a short interval is flowed into the circuit in FIG. 5. Before the pulse noise is flowed into, the input signal Vin and the output signal Vout all have a low level Low, and both of output values of the NAND gate NAND and the NOR gate NOR are a high level High. Therefore, the PMOS switch MP3 is in a turned-off state, and the NMOS switch MN3 is in a turned-on state. When a first pulse noise is flowed into the input signal Vin at a time t1, the filter signal Vfilter is gradually increased by the filter circuit 110a. At a time t2 before the pulse noise reference time ΔT passes from the time t1, the input signal becomes to have a low level Low again. Since the input signal Vin and the output signal Vout all have a low level Low, an output value of the NOR gate

NOR is a high level High. Then the NMOS switch MN3 is turned on, and the filter signal Vfilter is rapidly reset to have a low level Low. The PMOS switch MP3 is still in a turned-off state. When a second pulse noise is flowed into at a time t4, the filter signal Vfilter is gradually increased by the same process as described above. When the second pulse noise becomes to have a low level Low at a time t5, the filter signal Vfilter is rapidly reset to have a low level Low.

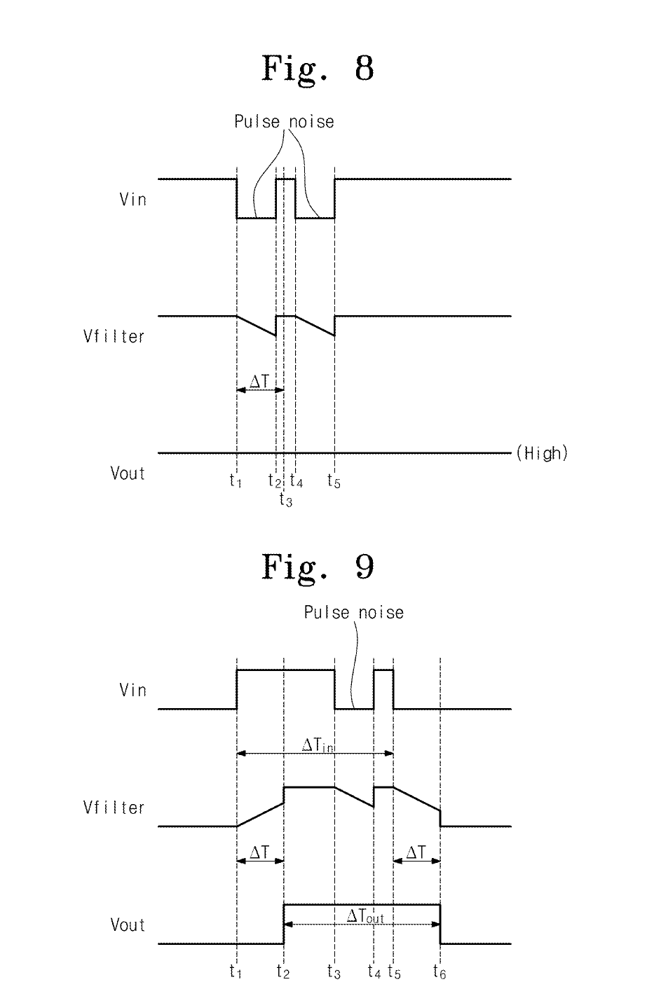

FIG. 8 is a timing diagram illustrating a pulse noise suppression method when a continuous pulse noise having a low level Low at a short interval is flowed into the circuit in FIG. 5. Before the pulse noise is flowed into, the input signal Vin and the output signal Vout all have a high level High, and output values of the NAND gate NAND and the NOR gate NOR all have a low level Low. Therefore, the PMOS switch MP3 is in a turn-on state and the NMOS switch MN3 is in a turned-off state. When a first pulse noise is flowed into the input signal Vin at a time t1, the filter signal Vfilter is gradually decreased by the filter circuit 110a. At a time t2 before the pulse noise reference time ΔT passes from the time t1, the input signal Vin becomes to have a high level High again. Since the input signal Vin and the output signal Vout all have a high level High, an output value of the NAND gate NAND is a low level Low. Then the PMOS switch MP3 is turned on, and the filter signal Vfilter is rapidly reset to have a high level High. The NMOS switch MN3 is still in a turned-off state. When a second pulse noise is flowed into at a time t4, the filter signal Vfilter is gradually decreased by the same process as described above. When the second pulse noise becomes to have a low level Low at a time t5, the filter signal Vfilter is rapidly reset to have a high level High.

By the above described process, even though a continuous pulse noise at a short interval is applied as an input, an overlap of the filter signal Vfilter, which occurs in a typical technology, does not occur, and an error pulse is not generated in the output signal Vout.

FIG. 9 is a timing diagram illustrating a pulse noise suppression method, when a pulse noise of a low level Low is flowed into an input signal of a high level High in the circuit in FIG. 5. When the input signal Vin is input at a time t1, the filter signal Vfilter is gradually increased by the filter circuit 110a. At a time t2 after the pulse noise reference time ΔT passes from the time t1, the filter signal Vfilter is reset to have a high level High by the level reset circuit 120. When a pulse noise is flowed into the input signal Vin at a time t3, the filter signal Vfilter is gradually decreased by the filter circuit 110a. At a time t4 before the pulse noise reference time ΔT passes from the time t3, the input signal Vin becomes to have a high level High again. Therefore, the filter signal Vfilter is reset to have a high level High by the level reset circuit 120. At a time t5, the input signal Vin becomes to have a low level Low, and the filter signal Vfilter is gradually decreased by the filter circuit 110a. At a time t6 after the pulse noise reference time ΔT passes from the time t5, the output signal Vout becomes to have a low level Low by the output circuit 130a. Therefore, the filter signal Vfilter is reset to have a low level Low by the level reset circuit 120. Through these processes, when a pulse noise is flowed into the input signal Vin having a pulse width of ΔTin, a pulse width ΔTout of the output signal Vout may be prevented from being shorter than the pulse width of ΔTin of the input signal Vin.

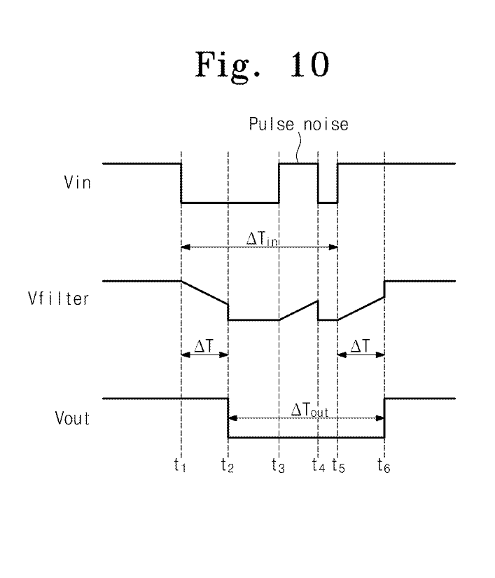

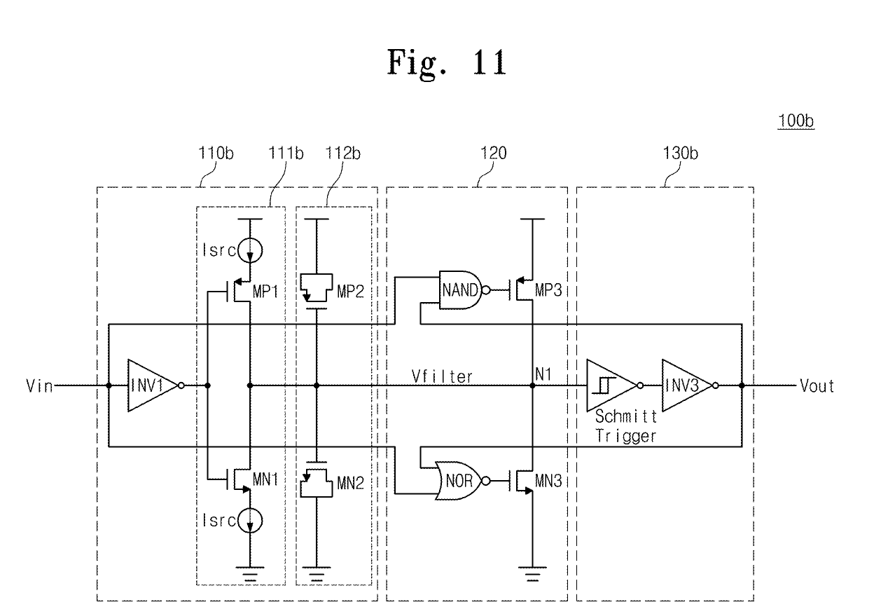

FIG. 10 is a timing diagram illustrating a pulse noise suppression method when a pulse noise having a high level High is flowed into the input signal having a low level Low in the circuit in FIG. 5. When the input signal Vin is input at a time t1, the filter signal Vfilter is gradually decreased by the filter circuit 110a. At a time t2 after the pulse noise reference time ΔT passes from the time t1, the filter signal Vfilter is reset to have a low level Low by the level reset circuit 120. When a pulse noise is flowed into the input signal Vin at a time t3, the filter signal Vfilter is gradually increased by the filter circuit 110a. At a time t4 before the pulse noise reference time ΔT passes from the time t3, the input signal Vin becomes to have a low level Low again. Therefore, the filter signal Vfilter is reset to have a low level by the level reset circuit 120. At a time t5, the input signal Vin becomes to have a high level High, and the filter signal Vfilter is gradually increased by the filter circuit 110a. At a time t6 after the pulse noise reference time ΔT passes from the time t5, the output signal Vout becomes to have a high level High by the output circuit 130a. Therefore, the filter signal Vfilter is reset to have a high level High by the level reset circuit 120. Through these processes, when a pulse noise is flowed into the input signal Vin having a pulse width ΔTin, a pulse width ΔTout of the output signal Vout may be prevented from being shorter than the pulse width ΔTin of the input signal Vin.

FIG. 11 is a detailed circuit diagram of a pulse noise suppression circuit according to another embodiment of the present invention. A pulse noise reference time of the circuit in FIG. 11 is defined to be ΔT′. By configuring a circuit as shown in FIG. 11, a case may be easily implemented where the pulse noise reference time ΔT′ is required to be set to be longer than the pulse noise reference time ΔT of the circuit in FIG. 5. The operation principle of the pulse noise suppression circuit 100b is basically the same as that of the pulse noise suppression circuit 100a in FIG. 5.

In order to set the pulse noise reference time ΔT′ to be long, the driver circuit 111b of the filter circuit 110b includes a current source Isrc and two switches MP1 and MN1. The current source Isrc of the driver circuit 111b adjusts an amount of a current flowing through the transistor MP1 and MN1. Accordingly, since a charging/discharging speed of the capacitor circuit 111b may be greatly lowered, a rate of voltage rise/voltage drop of the filter signal Vfilter may be lowered. Then a time for a voltage level of the filter signal Vfilter reaching the reference voltage of the output circuit 130b becomes longer. Accordingly, the pulse noise reference time ΔT′ may be set to be long.

In order to set the pulse noise reference time ΔT′ to be long, the output circuit 130b includes a Schmitt trigger and an inverter INV3. A typical inverter has a single threshold voltage value. In contrast, the Schmitt trigger has two different threshold voltage values when an input voltage increases or decreases. Therefore, by using the Schmitt trigger, a time for a voltage level of the filter signal Vfilter reaching the reference voltage of the output circuit 130b becomes longer. Accordingly the pulse noise reference time ΔT′ can be set to be long.

The current source Isrc in the driver circuit 111b and the Schmitt trigger in the output circuit 130b may be used separately. When the current source Isrc in the driver circuit 111b and the Schmitt trigger in the output circuit 130b are combined to be used, the pulse noise reference time ΔT′ can be set to be longer.

FIG. 12 is a timing diagram illustrating an effect of the circuit in FIG. 11. FIG. 12 shows that the pulse noise reference time ΔT′ is lengthened by the pulse noise suppression circuit 100b in FIG. 11. Referring to FIG. 12, Normal signal denotes a normal pulse signal, Pulse noise 1 denotes a pulse noise capable of being suppressed by the circuit in FIG. 5. Pulse noise 2 denotes a pulse noise shorter than Normal signal and longer than Pulse noise 1. When a pulse noise Pulse noise 2 is flowed into the input signal Vin, the filter signal Vfilter is gradually increased. A rate of voltage rise of the filter signal Vfilter is smaller than those of the filter signals Vfilter in FIGS. 6 to 10. Since the voltage level of the filter signal Vfilter does not reach the reference voltage of the output circuit 130b at a time t3, the filter signal Vfilter is not reset to have a high level High. The filter signal Vfilter continuously increases and then is reset to have a low level Low at a time t4 when the pulse noise Pulse noise 2 becomes to have a low level Low. In that process, the Schmitt trigger plays a role of raising higher the reference voltage of the output circuit 130b than a typical inverter. Accordingly, the pulse noise reference time ΔT′ is determined by combining the rate of voltage rise of the filter signal Vfilter due to the filter circuit 110b and the reference voltage of the output circuit 130b. Therefore, the pulse noise reference time ΔT′ of the circuit in FIG. 11 becomes longer than the pulse noise reference time ΔT of the circuit in FIG. 5. Hitherto, a case where the filter signal Vfilter increases is mainly described. It is easily understood to those skilled in the art that the reverse case, namely, a case where the filter signal Vfilter decreases can be valid.

According to embodiments of the present invention, an error signal due to inflow of continuous pulse noise can be suppressed and a pulse noise can be suppressed without changes in widths of input/output pulses. A pulse noise suppression circuit miniaturized through a simple configuration can be provided. In addition, a pulse noise suppression circuit having low power consumption without any separate delay circuit can be provided. The present invention provides a method of enhancing reliability in digital signal transmission and reception. Therefore, the present invention may be applied to all the circuits performing digital signal transfer.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A pulse noise suppression circuit, comprising:
a filter circuit converting an input signal of a pulse type into an increasing or decreasing filter signal;
a level reset circuit resetting the filter signal in response to the input signal and an output signal; and
an output circuit converting the filter signal into the output signal of a pulse type,
wherein the level reset circuit resets the filter signal to have a high level when the input signal and the output signal all have a high level, and resets the filter signal to have a low level when the input signal and the output signal all have a low level.

2. The circuit of claim 1, wherein the level reset circuit does not reset the filter signal when the input signal and the output signal have different levels.

3. The circuit of claim 1, wherein the filter circuit comprises a driver circuit adjusting a current amount flowing through the filter circuit.

4. The circuit of claim 3, wherein the driver circuit comprises an inverter lowering a rate of voltage rise of the filter signal.

5. The circuit of claim 3, wherein the driver circuit comprises:
a P-channel metal-oxide-semiconductor (PMOS) switch lowering a rate of voltage rise of the filter signal;
an N-channel metal-oxide-semiconductor (NMOS) switch lowering the rate of voltage rise of the filter signal;
a current source connected to a source of the PMOS switch; and
a current source connected to a source of the NMOS switch,
wherein a drain of the PMOS switch is connected to a drain of the NMOS switch.

6. The circuit of claim 3, wherein the filter circuit comprises a capacitor circuit charging or discharging an output signal of the driver circuit.

7. The circuit of claim 6, wherein the capacitor circuit comprises at least one of a parasitic capacitor distributed in the filter circuit and performing a charging or discharging function, a MOS capacitor including transistors, and a capacitor formed by laminating an dielectric film and a conductor film.

8. The circuit of claim 1, the level reset circuit comprises:
a PMOS switch, a drain of which is connected to an output stage of the filter circuit;
an NMOS switch, a drain of which is connected to the output stage of the filter circuit;
a NAND gate controlling the PMOS switch in response to the input and output signals; and
a NOR gate controlling the NMOS switch in response to the input and output signals.

9. The circuit of claim 8, wherein a source of the PMOS switch is connected to a power supply stage, a gate of the PMOS switch is connected to an output terminal of the NAND gate, a source of the NMOS switch is connected to a ground, and a gate of the NMOS switch is connected to an output terminal of the NOR gate.

10. The circuit of claim 1, wherein the output circuit comprises an inverter converting the filter signal into the output signal of a pulse type according to a reference voltage in response to the filter signal.

11. The circuit of claim 1, wherein the output circuit comprises a Schmitt trigger converting the filter signal into the output signal of a pulse type according to different reference voltages in response to the filter signal .

12. A pulse noise suppression method, comprising:
converting an input signal of a pulse type into a filter signal of an increasing or decreasing type;
performing a reset operation of the filter signal in response to the input signal and an output signal; and
converting the filter signal into the output signal of a pulse type,
wherein, in the performing of a reset operation, when the input and output signals all have a high level, the filter signal is reset to have a high level, and when the input and output signals all have a low level, the filter signal is reset to have a low level.

13. The method of claim 12, wherein, in the performing of a reset operation, when the input and output signals have different levels, the filter signal is not reset.

14. The method of claim 12, wherein, in the converting of the input signal, a current amount is controlled to control a rate of voltage rise or a rate of voltage drop of the filter signal.

15. The method of claim 12, wherein, in the converting of the input signal, the input signal is converted to the filter signal of an increasing or decreasing type through charging or discharging.

16. The method of claim 12, wherein, in the converting of the filter signal, the filter signal is converted to the output signal of a pulse type according to a reference voltage.

17. The method of claim 12, wherein, in the converting of the filter signal, the filter signal is converted to the output signal of a pulse type according to two different reference voltages.
